(19) United States
(12) Patent Application Publication
(10) Pub. No.: US 2021/0050275 A1
(43) Pub. Date: Feb. 18, 2021

(54) FAN-OUT SEMICONDUCTOR PACKAGE STRUCTURE AND PACKAGING METHOD THEREOF

(71) Applicant: Powertech Technology Inc., Hukou Township (TW)

(72) Inventors: Shang-Yu CHANG-CHIEN, Hukou Township, Hsinchu County (TW); Hung-Hsin HSU, Hukou Township, Hsinchu County (TW); Nan-Chun LIN, Hukou Township, Hsinchu County (TW)

(73) Assignee: Powertech Technology Inc., Hukou Township (TW)

(21) Appl. No.: 16/741,358

(22) Filed: Jan. 13, 2020

(30) Foreign Application Priority Data
Aug. 15, 2019 (TW) 108129135

(51) Int. Cl. H01L 23/31; H01L 23/29; H01L 23/64; H01L 23/00

(52) U.S. Cl. CPC H01L 23/3157; H01L 23/298; H01L 2924/18161; H01L 24/05; H01L 2224/02379; H01L 23/64

(57) ABSTRACT

A fan-out semiconductor package and packaging method thereof are disclosed. In the packaging method, a photosensitive material is used to encapsulate multiple bare chips and multiple passive devices, so multiple metal pads of each bare chip and multiple metal terminals of each passive device are exposed out of the photosensitive material by a photolithography process. The exposed metal pads and the exposed metal terminals are directly and electrically connected to a redistribution layer. In the packaging method, the bare chips and the passive devices are located on the same side of the redistribution layer and encapsulated by the photosensitive material. In addition, in the packaging method, the bare chips are not processed by a wafer bump process and does not use the thinner passive devices with high cost. Therefore, a height of the fan-out semiconductor package of the present invention is decreased and a manufacturing cost is relatively reduced.

### CROSS-REFERENCE TO RELATED APPLICATIONS

This application is based upon and claims priority under 35 U.S.C. 119 from Taiwan Patent Application No. 108129135 filed on Aug. 15, 2019, which is hereby explicitly incorporated herein by this reference thereto.

### BACKGROUND OF THE INVENTION

### 1. Field of the Invention

The present invention is related to a semiconductor package, and more particularly to a fan-out semiconductor package and packaging method thereof.

### 2. Description of the Prior Arts

In a procedure of packaging a fan-out semiconductor package, the bare chip may be packaged directly or be packaged after a bumping step. Using the fan-out semiconductor package including bare chip without bumps as an example, when the fan-out semiconductor package further integrates passive component therein, the bare chip and the passive component are respectively mounted on two opposite surfaces of a redistribution layer of the fan-out semiconductor package. In other words, the passive component and multiple solder balls are mounted on the same surface of the redistribution layer, but the passive component is not mounted on the same surface on which the bare chip is mounted. Therefore, an encapsulation of the fan-out semiconductor package does not encapsulate the bare chip and the passive component at the same time.

Furthermore, when the fan-out semiconductor package is mounted on a circuit board, heights of the solder balls are increased to avoid that the passive component hit to the circuit board. However, a height of the fan-out semiconductor package and a packaging cost are relatively increased accordingly.

To overcome the shortcomings, the present invention provides a new fan-out semiconductor package and packaging method thereof to mitigate or obviate the aforementioned problems.

### SUMMARY OF THE INVENTION

The objective of the present invention provides a fan-out semiconductor package and packaging method thereof to overcome the drawbacks as mentioned above.

To achieve the objective, the fan-out semiconductor package has a redistribution layer, a bare chip, a passive device, a photosensitive encapsulation. The redistribution layer has two opposite first and second surfaces. Multiple first inner pads and multiple second inner pads are formed on the first surface. Multiple outer terminals are formed on the second surface. The bare chip has two opposite active surface and a rear surface. Multiple metal pads are formed on the active surface and directly and electrically connected to the corresponding first inner pads of the redistribution layer. The passive device has two opposite third and fourth surfaces. Multiple metal terminals are formed on the third surface and electrically connected to the corresponding second inner pads of the redistribution layer. The photosensitive encapsulation is formed on the first surface of the redistribution layer and encapsulates the bare chip and passive device.

In the present invention, since the photosensitive encapsulation is used to encapsulate the bare chip and passive device, the metal pads of the bare chip and the metal terminals of the passive device are exposed out of the photosensitive encapsulation by a photolithography process. The exposed metal pads and the exposed metal terminals are directly and electrically connected to the redistribution layer. Therefore, the passive device and the bare chip are coplanar and encapsulated by the photosensitive encapsulation. In addition, the present invention uses the bare chip, which is not processed by a wafer bump process and does not use a thinner passive device with high cost. Therefore, a height of the fan-out semiconductor package of the present invention is decreased and a manufacturing cost is relatively reduced.

To achieve the objective, the fan-out semiconductor packaging method has steps of:

(a) providing a carrier;

(b) attaching multiple bare chip and multiple passive devices on the carrier, wherein a rear surface of each bare chip is attached on the carrier, an active surface of each bare chip is far away from the carrier, a first surface of each passive device attached on the carrier and a second surface of each passive device opposite to the first surface is also far away from the carrier;

(c) forming a photosensitive material on the carrier to encapsulate the bare chips and the passive devices;

(d) forming multiple first openings and multiple second openings on a first side of the photosensitive material by a photolithography process, wherein each of the first openings corresponds to a one of metal pads on the active surface of the bare chip and each of the second openings corresponds to one of the metal terminals on the second surface of the passive device;

(e) forming a redistribution layer on the first side of the photosensitive material by a redistribution layer process;

(f) removing the carrier;

(g) forming multiple outer terminals on the redistribution layer; and

(h) cutting the photosensitive material to separate multiple independent fan-out semiconductor packages, wherein each fan-out semiconductor package has at least one bare chip and at least one passive device.

Based on the foregoing description, since the photosensitive material is used to encapsulate the bare chips and passive devices, the metal pads of each bare chip and the metal terminals of each passive device are exposed out of the photosensitive material by the photolithography process. The exposed metal pads and the exposed metal terminals are directly and electrically connected to the redistribution layer. Therefore, in the method of the present invention, the passive devices and the bare chips are coplanar and encapsulated by the photosensitive material. In addition, the present invention uses the bare chips which are not processed by a wafer bump process and does not use the thinner passive devices with high cost. Therefore, a height of the fan-out semiconductor package of the present invention is decreased and a manufacturing cost is relatively reduced.

Other objectives, advantages and novel features of the invention will become more apparent from the following detailed description when taken in conjunction with the accompanying drawings.

### BRIEF DESCRIPTION OF THE DRAWINGS

FIG. 1A is a cross-sectional view of a first embodiment of a fan-out semiconductor package in accordance with the present invention;

FIG. 1B is a cross-sectional view of a first embodiment of a fan-out semiconductor package in accordance with the present invention; and

FIGS. 2 to 9 are cross-sectional views in different steps of a fan-out semiconductor packaging method in accordance with the present invention.

### DETAILED DESCRIPTION OF THE PREFERRED EMBODIMENTS

The present invention provides a fan-out semiconductor package and packaging method and the present invention is described in detail as follow by providing multiple embodiments and related drawings.

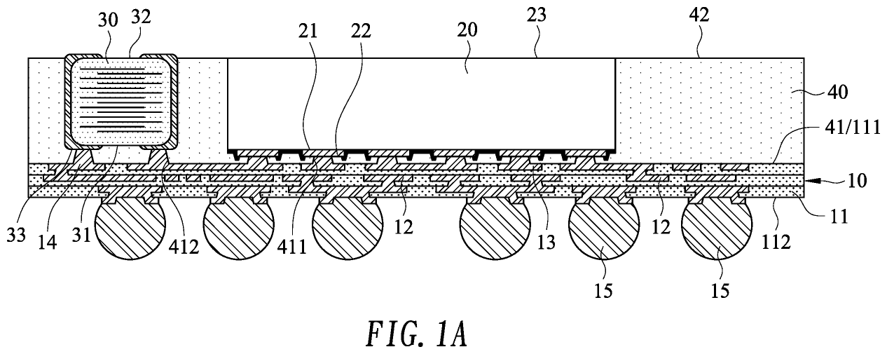

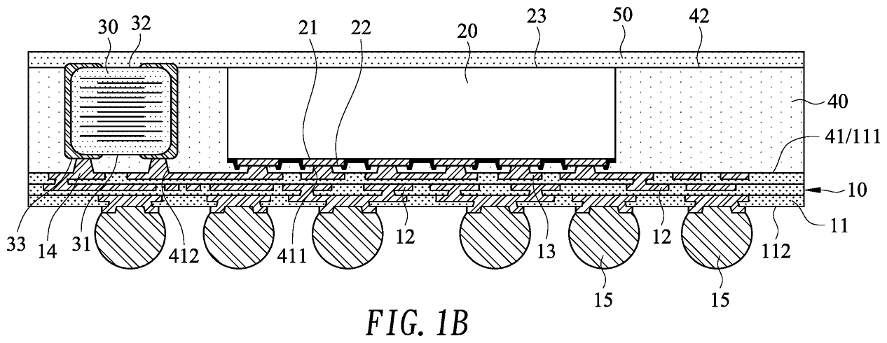

With reference to FIG. 1A, a cross-sectional view of a first embodiment of a fan-out semiconductor package of the present invention is shown. The fan-out semiconductor package has a redistribution layer 10, at least one bare chip 20, at least one passive device 30 and a photosensitive encapsulation 40. In one embodiment, the fan-out semiconductor package has but not limited to a bare chip 20 and a passive device 30.

The redistribution layer 10 has a dielectric insulation body 11, multiple interconnections 12, multiple first inner pads 13, multiple second inner pads 14 and multiple outer terminals 15. The dielectric insulation body 11 has two opposite first and second surfaces 111, 112. The first inner pads 13 and the second inner pads 14 are formed on the first surface 111. The outer terminals 15 are formed on the second surface 112. The interconnections 12 are formed inside the dielectric insulation body 11 and electrically connected to the first and second inner pads 13, 14 and the outer terminals 15. In one embodiment, the dielectric insulation body 11 may be PI, PBO, BCB, or the like and may be a material of the photosensitive encapsulation. If the dielectric insulation body 11 may be the material of the photosensitive encapsulation, compatibility between the redistribution layer 10 and photosensitive encapsulation 40 is increased and a natural material difference between the redistribution layer 10 and photosensitive encapsulation 40 is minimized. In addition, the coefficient of thermal expansion (CTE) of the redistribution layer 10 matches that of the photosensitive encapsulation 40, so warpage therebetween is not occurred. In one embodiment, the outer terminal may be a solder ball.

The bare chip 20 has two opposite active surface 21 and rear surface 23. Multiple metal pads 22 are formed on the active surface 21, and the active surface faces to the first surface 111 of the redistribution layer 10. The metal pads 22 are directly and electrically connected to the corresponding first inner pads 13 of the redistribution layer 10. The rear surface 23 is far away from the redistribution layer 10.

The passive device 30 has two opposite third surface 31 and fourth surface 32. Multiple metal terminals 33 are formed on the third surface 31. The third surface 31 faces to the first surface 111 of the redistribution layer 10 and the metal terminals 33 are electrically connected to the corresponding second inner pads 14 of the redistribution layer 10. The fourth surface is far away from the redistribution layer 10. In one embodiment, the metal terminals 33 of the passive device 30 is made of metal material with a melting point higher than a melting point of solders, such as copper or the like.

The photosensitive encapsulation 40 is formed on the first surface 111 of the redistribution layer 10 and encapsulates the bare chip 20 and the passive device 30. Multiple first openings 411 and multiple second openings 412 are formed on a first side 41 of the photosensitive encapsulation 40. The first openings 411 respectively correspond to the metal pads 22 of the bare chip 20 and the second openings 412 respectively correspond to the metal terminals 33 of the passive device 30. The first and second openings 411, 412 are formed in the same photolithography process. A diameter of the first opening 411 is the same as or different from that of the second opening 412. A depth of the first opening 411 is the same as or different from that of the second opening 412. In one embodiment, the rear surface 23 of the bare chip 20 and the fourth surface 32 of the passive device 30 are exposed out of a second side of the photosensitive encapsulation 40. The rear surface 23 of the bare chip 20, the fourth surface 32 of the passive device 30 and the second side of the photosensitive encapsulation 40 are coplanar. A height difference between the active surface 21 of the bare chip 20 and the third surface 31 of the passive device 30 is existed, so the depth of the first opening 411 is less than that of the second opening 412. In one embodiment, the photosensitive encapsulation 40 is made of a silicone base photosensitive material, such as siloxane polymers (SINR).

With reference to FIG. 1B, a fan-out semiconductor package of a second embodiment of the present invention is similar to that of the first embodiment shown in FIG. 1A, but a protection layer 50 is further formed on the rear surface 23 of the bare chip 20, the fourth surface 32 of the passive device 30 and the second side of the photosensitive encapsulation 40. Particularly, the protection layer 50 is made of a black material for marking or is made of a glue material with high thermal conductivity for increasing heat dissipation.

Based on the foregoing description, as shown in 1A, since the bare chip 20 and the passive device 30 are mounted on the first surface 111 of the redistribution layer 10, and the photosensitive encapsulation 40 encapsulates the bare chip 20 and passive device 30, the metal pads 22 of the bare chip 20 and the metal terminal 33 of the passive device 30 are exposed out of the first side of the photosensitive encapsulation 40 by the photolithography process. Therefore, the exposed metal pads 22 and the metal terminals 33 are directly and electrically connected to the redistribution layer 10.

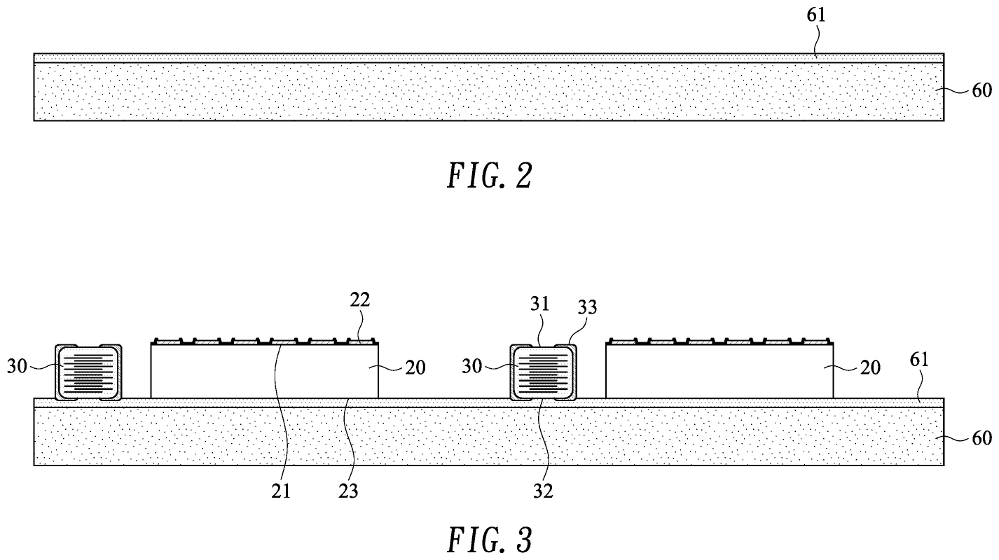

With reference to FIGS. 2 to 9, a fan-out semiconductor package of the present invention has following steps.

In FIG. 2, a carrier 60 is provided, and an adhesive layer 61 is formed on the carrier 60. In addition, a resin layer may be further formed on the adhesive layer 61. In one embodiment, the carrier 60 may be but not limited to glass board, ceramic board, metal board or fiber-reinforced board.

In FIG. 3, the bare chips 20 and the passive devices 30 are attached on the carrier 60 through the adhesive layer 61. The rear surface 23 of the bare chip 20 and the fourth surface 32 of the passive device 30 face to and are attached on the carrier 60, so the rear surface 23 of the bare chip 20 and the fourth surface 32 of the passive device 30 are coplanar. The active surface 21 of the bare chip 20 and the third surface 31 of the passive device 30 is far away from the carrier 60. In one embodiment, the bare chip 20 is not processed by the wafer bump process, so no bump is formed on each of the metal pads 22. In one embodiment, a thickness of the passive device 30 is thinner than that of the bare chip 20, so the active surface 21 of the bare chip 20 is higher than the third surface 31 of the passive device 30. In another embodiment, the thickness of the passive device 30 may be the same as that of the bare chip 20 or slightly larger than that of the bare chip 20. In one embodiment, the metal terminals 33 of the passive device 30 is made of metal material with a melting point higher than a melting point of solders, such as copper or the like.

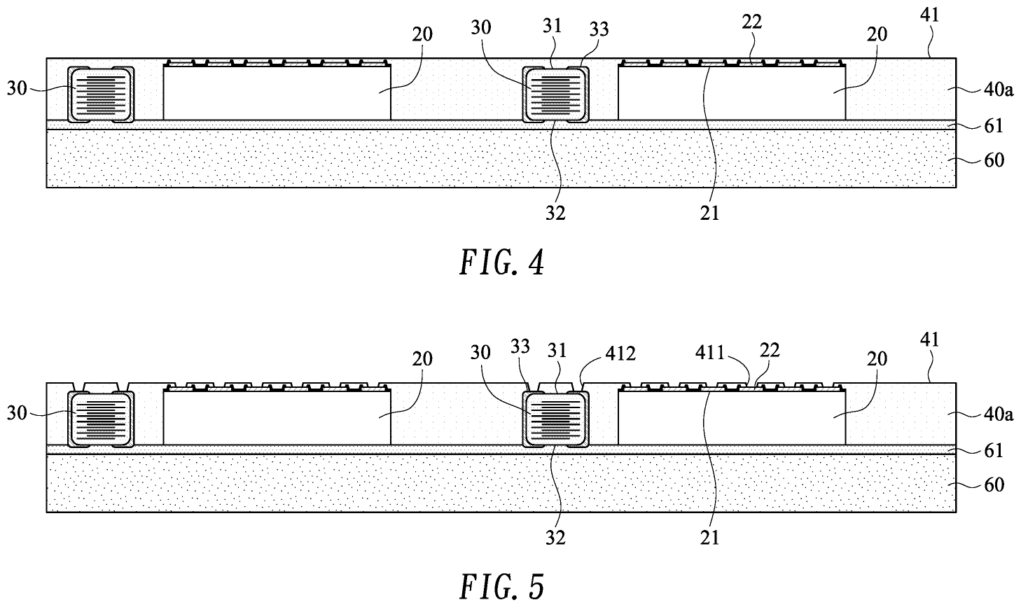

In FIG. 4, a photosensitive material 40a covers on the carrier 60 to encapsulate the bare chips 20 and passive devices 30. A first side of the photosensitive material 40a corresponds to the active surface 21 of each bare chip 20 and the third surface 31 of each passive device 30. The photosensitive material 40a may be liquid glue to be coated on the carrier 60, and then the photosensitive material 40a is solidified to be used as the photosensitive encapsulation 40 to encapsulate the bare chips 20 and the passive devices 30. The photosensitive material 40a may be a glue film and encapsulate the bare chips 20 and the passive devices 30 in a lamination process. In one embodiment, the photosensitive material 40a is a silicone base photosensitive material, such as siloxane polymers (SINR).

With reference to FIG. 5, multiple first openings 411 and multiple second openings 412 are formed on the first side 41 of the photosensitive material 40a. The first openings 411 respectively correspond to the metal pads 22 of the bare chips 20 and the second openings 412 respectively correspond to the metal terminals 33 of the passive devices 30. In one embodiment, a diameter of the first opening 411 is smaller than that of the second opening 412, since each metal pad 22 is smaller than each metal terminal 33. In one embodiment, the depth of the first opening 411 is less than that of the second opening 412, since the active surfaces 21 of the bare chips 20 is higher than the third surfaces 31 of the passive devices 30. In another embodiment, if the thickness of each bare chip 20 is substantially same as that of each passive device 30, the depth of each first opening 411 is substantially same as that of each second opening 412. In another embodiment, the depth of the first opening 411 is larger than that of the second opening 412, if the thickness of each bare chip 20 is substantially thinner than that of each passive device 30. Different fan-out semiconductor packages require different thicknesses of the bare chips or the passive devices.

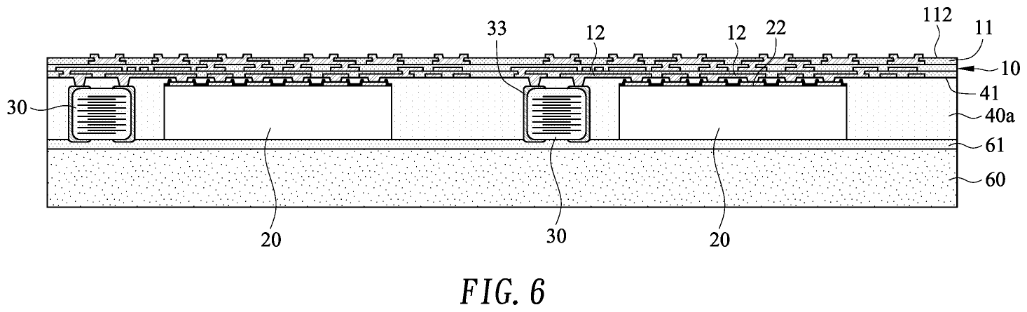

With reference to FIG. 6, the redistribution layer 10 is formed on the first side 41 of the photosensitive material 40a by the redistribution process. Since the first and second openings 411, 412 are previously formed on the first side 41, and the metal pads 22 and the metal terminals 33 are exposed out of the photosensitive material 40a, the redistribution layer 10 is directly and electrically connected to the metal pads 22 and the metal terminals 33. According to requirements for different fan-out semiconductor package, several dielectric insulation layers for the dielectric insulation body, and several interconnection layers are different. In one embodiment, the dielectric insulation layer may be PI, PBO, BCB or the like and may be a material of the photosensitive material. If the dielectric insulation layer may be the photosensitive material, the compatibility between the redistribution layer 10 and the photosensitive material 40a is increased, and a natural material difference between the redistribution layer 10 and photosensitive material 40a is minimized. In addition, the coefficient of thermal expansion (CTE) of the redistribution layer 10 matches that of the photosensitive material 40a, so warpage therebetween is not occurred.

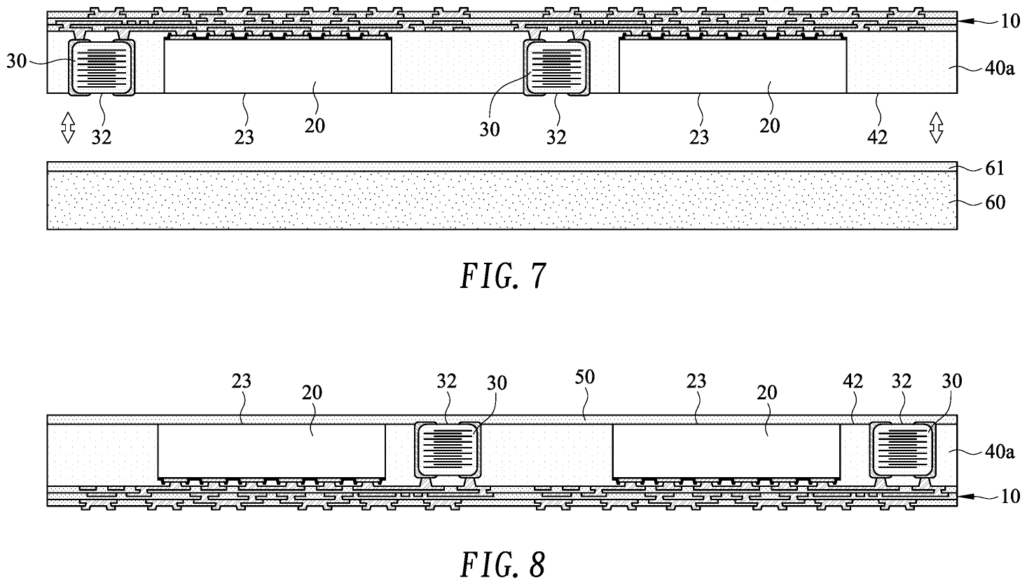

With reference to FIG. 7, the carrier is removed, so the rear surface 23 of each bare chip 20, the fourth surface 32 of each passive device 30 and the second side 42 of the photosensitive material 40a are exposed in the air and coplanar. In one embodiment, as shown in FIG. 8, the protection layer 50 is further formed on the coplanar rear surface 23, the fourth surface 32, and the second side 42. Particularly, the protection layer 50 is made of black material for marking or is made of a glue material with high thermal conductivity for increasing heat dissipation.

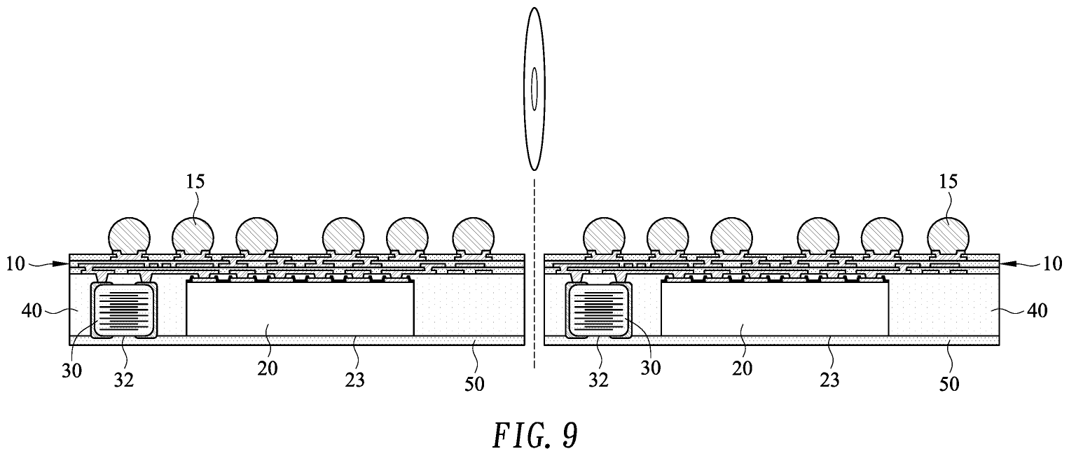

With reference to FIG. 9, the outer terminals 15 are formed outside the redistribution layer 10. In one embodiment, each outer terminal is a solder ball.

With reference to FIG. 9, a step of cutting is performed. In the cutting step, the photosensitive material 40a is cut to separate multiple independent fan-out semiconductor packages. Each fan-out semiconductor package has at least one bare chip and at least one passive device.

Based on the foregoing description, in the packaging method of the present invention, since the photosensitive material is used to encapsulate the bare chips and passive devices, the metal pads of each bare chip and the metal terminals of each passive device are exposed out of the photosensitive material by the photolithography process. The exposed metal pads and the exposed metal terminals are directly and electrically connected to the redistribution layer. Therefore, in the method of the present invention, the passive devices and the bare chips are coplanar and encapsulated by the photosensitive material. In addition, the present invention uses the bare chips which are not processed by a wafer bump process and does not use the thinner passive devices with high cost. Therefore, a height of the fan-out semiconductor package of the present invention is decreased, and a manufacturing cost is relatively reduced.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A fan-out semiconductor package, comprising:
a redistribution layer having:
a first surface;
multiple first inner pads and multiple second inner pads formed on the first surface; and
a second surface opposite to the first surface; and
multiple outer terminals formed on the second surface;
a bare chip having:
an active surface;
multiple metal pads formed on the active surface and directly and electrically connected to the corresponding first inner pads of the redistribution layer; and
a rear surface opposite to the active surface;
a passive device having:
a third surface;
multiple metal terminals formed on the third surface and electrically connected to the corresponding second inner pads of the redistribution layer; and
a fourth surface opposite to the third surface; and
a photosensitive encapsulation is formed on the first surface of the redistribution layer and encapsulates the bare chip and passive device.

2. The fan-out semiconductor package as claimed in claim 1, wherein:
the rear surface of the bare chip, the fourth surface of the passive device and a second side of the photosensitive encapsulation are coplanar.

3. The fan-out semiconductor package as claimed in claim 2, wherein:
multiple first openings are formed on a first side of the photosensitive encapsulation and corresponds to the metal pads of the bare chip, wherein the first side is opposite to the second side; and
multiple second openings are formed on the first side of the photosensitive encapsulation and corresponds to the metal terminals of the passive device; wherein the first and second openings are formed in a same photolithography process.

4. The fan-out semiconductor package as claimed in claim 3, wherein:
a height difference between the active surface of the bare chip and the third surface of the passive device is existed; and
a depth of each first opening is less than that of each second opening.

5. The fan-out semiconductor package as claimed in claim 3, wherein:
a protection layer or a glue material with high thermal conductivity is formed on the rear surface of the bare chip, the fourth surface of the passive device and a second side of the photosensitive encapsulation.

6. The fan-out semiconductor package as claimed in claim 4, wherein:
a protection layer or a glue material with high thermal conductivity is formed on the rear surface of the bare chip, the fourth surface of the passive device and a second side of the photosensitive encapsulation.

7. The fan-out semiconductor package as claimed in claim 5, wherein:
the metal terminals of the passive device are made of copper;
the photosensitive encapsulation is made of a silicone base photosensitive material; and
each outer terminal is a solder ball.

8. The fan-out semiconductor package as claimed in claim 6, wherein:
the metal terminals of the passive device are made of copper;
the photosensitive encapsulation is made of a silicone base photosensitive material; and
each outer terminal is a solder ball.

9. The fan-out semiconductor package as claimed in claim 7, wherein a dielectric insulation body of the redistribution layer is made of a material of the photosensitive encapsulation.

10. The fan-out semiconductor package as claimed in claim 8, wherein a dielectric insulation body of the redistribution layer is made of a material of the photosensitive encapsulation.

11. A fan-out semiconductor packaging method, comprising steps of:
(a) providing a carrier;
(b) attaching multiple bare chip and multiple passive devices on the carrier, wherein a rear surface of each bare chip is attached on the carrier, an active surface of each bare chip is far away from the carrier, a first surface of each passive device attached on the carrier and a second surface of each passive device opposite to the first surface is also far away from the carrier;
(c) forming a photosensitive material on the carrier to encapsulate the bare chips and the passive devices;
(d) forming multiple first openings and multiple second openings on a first side of the photosensitive material by a photolithography process, wherein each of the first openings corresponds to a one of metal pads on the active surface of the bare chip and each of the second openings corresponds to one of the metal terminals on the second surface of the passive device;
(e) forming a redistribution layer on the first side of the photosensitive material by a redistribution layer process;
(f) removing the carrier;
(g) forming multiple outer terminals on the redistribution layer; and
(h) cutting the photosensitive material to separate multiple independent fan-out semiconductor packages, wherein each fan-out semiconductor package has at least one bare chip and at least one passive device.

12. The fan-out semiconductor packaging method as claimed in claim 11, wherein in the step of (f), after the carrier is removed, the rear surface of each bare chip, the second surface of each passive device and a second side of the photosensitive encapsulation are coplanar and then a protection layer of a glue material with high thermal conductivity is further formed on the rear surfaces, the second surfaces and the second side.

13. The fan-out semiconductor packaging method as claimed in claim 11, wherein:
in the step of (b), the metal terminals of the passive device are made of copper;
in the step (c), the photosensitive encapsulation is made of a silicone base photosensitive material; and
in the step (g), each outer terminal is a solder ball.

14. The fan-out semiconductor packaging method as claimed in claim 12, wherein:
in the step of (b), the metal terminals of the passive device are made of copper;
in the step of (c), the photosensitive encapsulation is made of a silicone base photosensitive material; and
in the step of (g), each outer terminal is a solder ball.

15. The fan-out semiconductor packaging method as claimed in claim 11, wherein in the step of (e), a dielectric insulation body of the redistribution layer is made of a material of the photosensitive encapsulation.

16. The fan-out semiconductor packaging method as claimed in claim 12, wherein in the step of (e), a dielectric insulation body of the redistribution layer is made of a material of the photosensitive encapsulation.

17. The fan-out semiconductor packaging method as claimed in claim 13, wherein in the step of (e), a dielectric insulation body of the redistribution layer is made of a material of the photosensitive encapsulation.

18. The fan-out semiconductor packaging method as claimed in claim 14, wherein in the step of (e), a dielectric insulation body of the redistribution layer is made of a material of the photosensitive encapsulation.
